(19) United States
(12) Patent Application Publication
(10) Pub. No.: US 2022/0081769 A1
(43) Pub. Date: Mar. 17, 2022

(54) METHODS OF ATOMIC LAYER DEPOSITION

(71) Applicant: Applied Materials, Inc., Santa Clara, CA (US)

(72) Inventors: Kendrick H. Chaney, Santa Clara, CA (US); Tatsuya E. Sato, San Jose, CA (US)

(73) Assignee: Applied Materials, Inc., Santa Clara, CA (US)

(21) Appl. No.: 17/019,599

(22) Filed: Sep. 14, 2020

(51) Int. Cl. C23C 16/455; C23C 16/40; H01L 21/02

(52) U.S. Cl. CPC C23C 16/45527; H01L 21/0228; C23C 16/45553; C23C 16/40

(57) ABSTRACT

Methods for depositing metal-containing films on a substrate are described. The substrate is exposed to a metal precursor and an in situ steam generated oxidant to form the metal-containing film (e.g., metal oxide). The exposures can be sequential or simultaneous. An atomic layer deposition method is described that includes a forming gas anneal operation as part of the deposition method.

### TECHNICAL FIELD

Embodiments of the present disclosure generally relate to methods for depositing metal films. In particular, embodiments of the disclosure are directed to methods of depositing metal films by atomic layer deposition in the presence of an in situ steam generated oxidant. Other embodiments are directed to methods of depositing metal films by atomic layer deposition with the addition of an in situ gas anneal step

### BACKGROUND

Deposition of films on a substrate surface is an important process in a variety of industries including semiconductor processing, diffusion barrier coatings, and dielectrics for magnetic read/write heads. In the semiconductor industry, in particular, miniaturization requires atomic level control of film deposition to produce conformal coatings on high aspect structures.

One method for deposition of films is atomic layer deposition (ALD). Most ALD processes are based on binary reaction sequences, where each of the two surface reactions occurs sequentially. Because the surface reactions are sequential, the two gas phase reactants are not in contact, and possible gas phase reactions that may form and deposit particles are limited.

As microelectronic device sizes become smaller, challenges exist with current metal films used for contacts, barrier layers, etc. Metal films and metal oxide films with improved electrical properties are needed for a variety of applications in microelectronic devices. Accordingly, there is a need in the art for new methods of depositing metal-containing films for microelectronic devices.

### SUMMARY

One or more embodiments of the disclosure are directed to methods of depositing a film. A substrate is exposed to a metal precursor to deposit a metal film on the substrate. The processing chamber is purged of the metal precursor and the substrate is exposed to an in situ steam generated oxidant to react with the metal film and form a metal oxide film on the substrate, the in situ steam generated oxidant comprising a mixture of ozone (O₃) and hydrogen (H₂). The processing chamber is then purged of the in situ steam generated oxidant.

Additional embodiments of the disclosure are directed to methods of depositing a film. A substrate is exposed to a metal precursor to deposit a metal film on the substrate. The processing chamber is purged of the metal precursor and the substrate is exposed to an oxidant to form a metal oxide film. The processing chamber is then purged of the oxidant, and the substrate is exposed to hydrogen (H₂) and nitrogen (N₂) to anneal the metal oxide film. The processing chamber is then purged of hydrogen (H₂) and nitrogen (N₂).

Further embodiments of the disclosure are directed to methods of depositing a film comprising selectively forming a metal oxide film in a process cycle comprising sequential exposure of a substrate to a metal precursor, purge gas, oxidant, purge gas, atmosphere of hydrogen (H₂) and nitrogen (N₂), and purge gas, wherein the atmosphere of hydrogen (H₂) and nitrogen (N₂) anneals the metal oxide film.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a flowchart of a processing method in accordance with one or more embodiments of the disclosure; and

FIG. 2 illustrates a flowchart of a processing method in accordance with one or more embodiments of the disclosure.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal oxides, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap. As used in this specification and the appended claims, the terms “precursor”, “reactant”, “reactive gas” and the like are used interchangeably to refer to any gaseous species that can react with the substrate surface.

A metal can be grown by atomic layer deposition for many applications. One or more embodiments of the disclosure advantageously provide processes for atomic layer deposition to form metal-containing films. As used in this specification and the appended claims, the term “metal-containing film” refers to a film that comprises metal atoms and has greater than or equal to about 1 atomic % metal, 2 atomic % metal, 3 atomic % metal, 4 atomic % metal, 5 atomic % metal, 10 atomic % metal, 15 atomic % metal, 20% atomic metal, 25% atomic metal, 30% atomic metal, 35% atomic metal, 40% atomic metal, 45% atomic metal, or 50% atomic metal. In some embodiments, the metal-containing film comprises one or more of a metal, a metal nitride, a metal carbide, or a metal oxide. The skilled artisan will recognize that the use of molecular formula like MN, where M is a metal, does not imply a specific stoichiometric relationship between the elements but merely the identity of the major components of the film. For example, MN refers to a film whose major composition comprises a metal and nitrogen atoms. In some embodiments, the major composition of the specified film (i.e., the sum of the atomic percent of the specified atoms) is greater than or equal to about 95%, 98%, 99% or 99.5% of the film, on an atomic basis.

In one or more embodiments, the metal may comprise any suitable metal known to the skilled artisan. In some embodiments, the metal is selected from one or more of aluminum (Al), zirconium (Zr), magnesium (Mg), hafnium (Hf), calcium (Ca), lanthanum (La), scandium (Sc), tantalum (Ta), titanium (Ti), niobium (Nb), yttrium (Y), gadolinium (Gd), zinc (Zn), indium (In), gallium (Ga), and tin (Sn). In specific embodiments, the metal comprises aluminum (Al), and the deposited film comprises aluminum oxide.

In one or more embodiments, the metal oxide film is selected from one or more of metal oxide film comprises one or more of aluminum oxide (Al₂O₃), zirconium oxide (ZrO₂), magnesium oxide (MgO), hafnium oxide (HfO₂), calcium oxide (CaO), lanthanum oxide (La₂O₃), scandium oxide (Sc₂O₃), tantalum oxide (Ta₂O₅), titanium oxide (TiO₂), niobium (Nb₂O₅), yttrium oxide (Y₂O₃), gadolinium oxide (Gd₂O₃), zinc oxide (ZnO), indium oxide (In₂O₃), gallium oxide (Ga₂O₃), and tin oxide (SnO₂).

Some embodiments of the disclosure advantageously provide metal oxide films with a variety of applications in microelectronic devices.

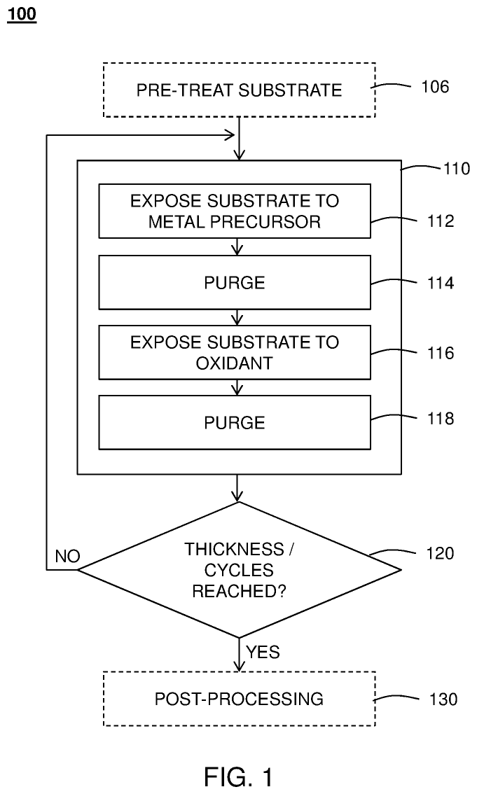

With reference to FIG. 1, one or more embodiments of the disclosure are directed to method 100 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the film.

In some embodiments, the method 100 includes a pre-treatment operation 106. The pre-treatment can be any suitable pre-treatment known to the skilled artisan. Suitable pre-treatments include, but are not limited to, pre-heating, cleaning, soaking, native oxide removal, or deposition of an adhesion layer (e.g. titanium nitride (TiN)). In one or more embodiments, an adhesion layer, such as titanium nitride, is deposited at operation 106.

At deposition 110, a process is performed to deposit a metal-containing film on the substrate (or substrate surface). The deposition process can include one or more operations to form a film on the substrate. In operation 112, the substrate (or substrate surface) is exposed to a metal precursor to deposit a film on the substrate (or substrate surface). The metal precursor can be any suitable metal-containing compound that can react with (i.e., adsorb or chemisorb onto) the substrate surface to leave a metal-containing species on the substrate surface.

In some embodiments, the metal precursor comprises an organometallic such as, but not limited to, trimethylaluminum, diethylzinc, organometallic zirconium precursors, tetrakis(dimethylamino)hafnium, or a metal halide such as, but not limited to, aluminum trichloride, hafnium tetrachloride, zirconium tetrachloride. As used in this manner, the term “consists essentially of” means that the metal precursor comprises greater than or equal to about 95%, 98%, 99% or 99.5% of the metal precursor, on a molecular basis. The presence of diluent, carrier and/or inert gases, for example, is not taken into consideration in the calculation.

In one or more embodiments, the substrate (or substrate surface) can be any suitable surface. Suitable surfaces include, but are not limited to, silicon (Si), silicon dioxide (SiO₂), silicon oxide (SiOₓ), silicon oxycarbide (SiOC), platinum (Pt), titanium nitride (TiN), tantalum nitride (TaN), copper (Cu), cobalt (Cu), tungsten (W), ruthenium (Ru), molybdenum (Mo) or combinations thereof.

At operation 114, the processing chamber is purged to remove unreacted metal precursor, reaction products and by-products. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the metal precursor by any suitable technique including, but not limited to, moving the substrate through a gas curtain to a portion or sector of the processing chamber that contains none or substantially none of the metal precursor. In some embodiments, purging the processing chamber comprises flowing a purge gas over the substrate. In one or more embodiments, the purge gas is selected from one or more of nitrogen (N₂), helium (He), and argon (Ar). In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur.

At operation 116, the substrate (or substrate surface) is exposed to an oxidant to form a metal oxide film. In one or more embodiments, the oxidant comprises an in situ steam generated (ISSG) oxidant. In some embodiments, a stream of ozone (O₃) and hydrogen (H₂) gas is co-flowed to generate steam in situ.

In one or more embodiments, ozone (O₃) gas is generated by an ozone generator. That gas is mixed with hydrogen (H₂) gas from the facilities near the reaction zone of the chamber. Because of safety concerns of mixing reactive gasses, the mixing point has to be at a low pressure. In one or more embodiments, a pressure switch is attached to the chamber and the pressure is maintained at 100 Torr or less during the mixing of the ozone (O₃) and hydrogen (H₂). In one or more embodiments, the ozone (O₃) and hydrogen (H₂) gases are mixed and flowed to a showerhead above a reaction zone where the gases then react with the metal species on the substrate to form a metal oxide film on the substrate.

In one or more embodiments, a gas source supplies oxygen gas (O₂) through a mass flow controller to an ozonator, which converts a large fraction of the oxygen to ozone gas (O₃). The resultant oxygen-based mixture of O₂ and O₃ and perhaps some oxygen radicals O* and ionized oxygen atoms or molecules is delivered into the processing chamber. In one or more embodiments, the stream of oxygen-containing gas is at least 30% ozone, or at least 70% ozone, or at least 80% ozone, or at least 90% ozone. Ozone is a metastable molecule which spontaneously quickly dissociates in the reaction.

In one or more embodiments, the ozone/oxygen containing gas mixture is combined with hydrogen (H₂) to increase the oxidation rate. In some embodiments, the hydrogen may be essentially pure hydrogen gas or be a forming gas of hydrogen (H₂)/nitrogen (N₂), for example having at least 7% hydrogen, or at least 10% hydrogen.

In one or more embodiments, an in situ steam generation (ISSG) process is used to mix the ozone/oxygen containing gas mixture and the hydrogen (H₂) gas. ISSG a low-pressure process (e.g. below 20 Torr) where the pre-mixed gases are introduced to the process chamber directly, without pre-combustion. Process gases are mixed and are then injected into the processing chamber, where they flow across a rotating substrate that is heated. The reaction between the ozone/oxygen and hydrogen occurs close to the substrate surface because the hot substrate acts as the ignition source. Steam is generated, which reacts with the metal species of the metal film on the surface of the substrate to form a metal oxide.

At operation 118, the processing chamber is purged after exposure to the oxidant. Purging the processing chamber in operation 118 can be the same process or different process than the purge in operation 114. Purging the processing chamber, portion of the processing chamber, area adjacent the substrate surface, etc., removes unreacted oxidant, reaction products and by-products from the area adjacent the substrate surface.

At decision point 120, the thickness of the deposited film, or number of cycles of metal-precursor and oxidant is considered. If the deposited film has reached a predetermined thickness or a predetermined number of process cycles have been performed, the method 100 moves to an optional post-processing operation 130. If the thickness of the deposited film or the number of process cycles has not reached the predetermined threshold, the method 100 returns to operation 110 to expose the substrate surface to the metal precursor again in operation 112, and continuing.

The optional post-processing operation 130 can be, for example, a process to modify film properties (e.g., annealing) or a further film deposition process (e.g., additional ALD or CVD processes) to grow additional films. In some embodiments, the post-processing operation 130 can be a process that modifies a property of the deposited film. In some embodiments, the post-processing operation 130 comprises annealing the as-deposited metal oxide film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

The method 100 can be performed at any suitable temperature depending on, for example, the metal precursor, oxidant or thermal budget of the device. In some embodiments, exposures to the metal precursor (operation 112) and the oxidant (operation 116) occur at the same temperature. In some embodiments, the substrate is maintained at a temperature in a range of about 300° C. to about 500° C., or in the range of about 350° C. to about 400° C.

In some embodiments, exposure to the metal precursor (operation 112) occurs at a different temperature than the exposure to the oxidant (operation 116). In some embodiments, the substrate is maintained at a first temperature in a range of about 300° C. to about 500° C. for the exposure to the metal precursor, and at a second temperature in the range of about 300° C. to about 500° C. for exposure the oxidant.

In the embodiment illustrated in FIG. 1, deposition operation 110 the substrate (or substrate surface) is exposed to the metal precursor and the oxidant sequentially. In another, un-illustrated, embodiment, the substrate (or substrate surface) is exposed to the metal precursor and the oxidant simultaneously in a CVD reaction. In a CVD reaction, the substrate (or substrate surface) can be exposed to a gaseous mixture of the metal precursor and in situ steam generated oxidant to deposit a metal oxide film having a predetermined thickness. In the CVD reaction, the metal oxide film can be deposited in one exposure to the mixed reactive gas, or can be multiple exposures to the mixed reactive gas with purges between.

In some embodiments, the metal oxide film formed comprises a metal selected from one or more of aluminum (Al), zirconium (Zr), magnesium (Mg), hafnium (Hf), calcium (Ca), lanthanum (La), scandium (Sc), tantalum (Ta), titanium (Ti), niobium (Nb), yttrium (Y), gadolinium (Gd), zinc (Zn), indium (In), gallium (Ga), and tin (Sn).

In other embodiments, the metal oxide film comprises metal oxide (MOₓ) with an oxygen content of greater than or equal to about 10%, greater than or equal to about 15%, greater than or equal to about 20%, greater than or equal to about 25%, greater than or equal to about 30%, greater than or equal to about 35%, greater than or equal to about 40%, greater than or equal to about 45%, greater than or equal to about 50%, greater than or equal to about 55%, or greater than or equal to about 60% on an atomic basis. In some embodiments, the metal-containing film comprises an oxygen content in the range of about 2% to about 65%, or in the range of about 3% to about 65%, or in the range of about 4% to about 6%, on an atomic basis.

The deposition operation 110 can be repeated to form a metal oxide film having a predetermined thickness. In some embodiments, the deposition operation 110 is repeated to provide a metal oxide film having a thickness in the range of about 0.3 nm to about 10 nm, or in the range of about 30 Å to about 3000 Å.

One or more embodiments of the disclosure are directed to methods of depositing metal oxide films in high aspect ratio features. A high aspect ratio feature is a trench, via or pillar having a height:width ratio greater than or equal to about 10, 20 or 50. In some embodiments, the metal oxide film is deposited conformally on the high aspect ratio feature. As used in this manner, a conformal film has a thickness near the top of the feature that is in the range of about 80-120% of the thickness at the bottom of the feature.

In some embodiments, the at least one feature extends a feature depth from a top surface of the substrate to a bottom surface, the at least one feature having a width defined by a first sidewall and a second sidewall.

Some embodiments of the disclosure are directed to methods for bottom-up gap fill of a feature. A bottom-up gap fill process fills the feature from the bottom versus a conformal process which fills the feature from the bottom and sides. In some embodiments, the feature has a first material at the bottom (e.g., a nitride) and a second material (e.g., an oxide) at the sidewalls. The metal oxide film deposits selectively on the first material relative to the second material so that the metal film fills the feature in a bottom-up manner.

As deposited, metal oxide ALD films often have bulk fixed charges and interface traps which contribute to leakage. Reducing this leakage is a high value problem for certain memory applications that use metal oxide films, e.g. aluminum oxide (Al₂O₃) as a dielectric. In one or more embodiments, the addition of a nitrogen (N₂)/hydrogen (H₂) gas treatment step to an ALD process flow treats each as-deposited layer to passivate dangling bonds and interface traps. In one or more embodiments, a forming gas anneal (N₂/H₂) is used in several shorter anneals to treat the layers as they are grown during the deposition of the metal oxide film. Accordingly, a long high temperature post-processing anneal step is not required, or the time of a post-processing anneal can be reduced.

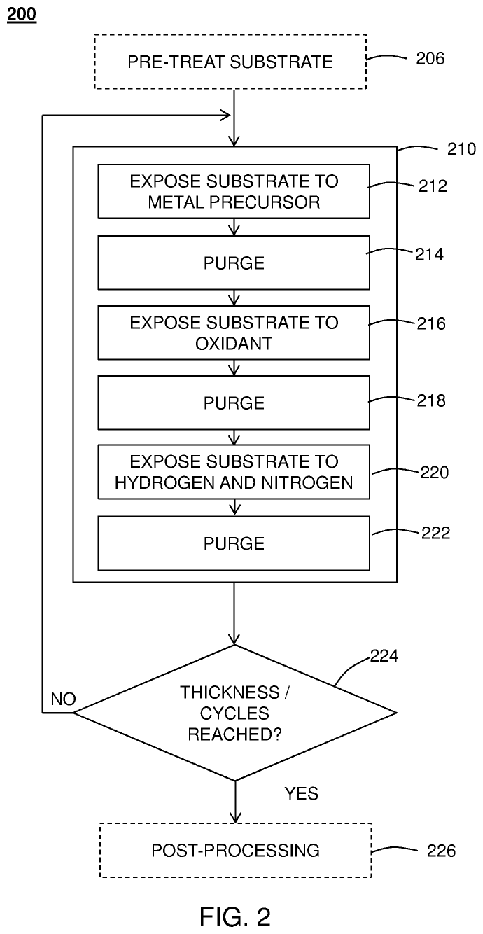

With reference to FIG. 2, one or more embodiments of the disclosure are directed to method 200 of depositing a film. The method illustrated in FIG. 2 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the film.

In some embodiments, the method 200 includes a pre-treatment operation 206. The pre-treatment can be any suitable pre-treatment known to the skilled artisan. Suitable pre-treatments include, but are not limited to, pre-heating, cleaning, soaking, native oxide removal, or deposition of an adhesion layer (e.g. titanium nitride (TiN)). In one or more embodiments, an adhesion layer, such as titanium nitride, is deposited at operation 206.

At deposition 210, a process is performed to deposit a metal-containing film on the substrate (or substrate surface). The deposition process can include one or more operations to form a film on the substrate. In operation 212, the substrate (or substrate surface) is exposed to a metal precursor to deposit a film on the substrate (or substrate surface). The metal precursor can be any suitable metal-containing compound that can react with (i.e., adsorb or chemisorb onto) the substrate surface to leave a metal-containing species on the substrate surface.

In some embodiments, the metal precursor comprises an organometallic such as, but not limited to, trimethylaluminum, diethylzinc, organometallic zirconium precursors, tetrakis(dimethylamino)hafnium, or a metal halide such as, but not limited to, aluminum trichloride, hafnium tetrachloride, zirconium tetrachloride. As used in this manner, the term “consists essentially of” means that the metal precursor comprises greater than or equal to about 95%, 98%, 99% or 99.5% of the metal precursor, on a molecular basis. The presence of diluent, carrier and/or inert gases, for example, is not taken into consideration in the calculation.

In one or more embodiments, the substrate (or substrate surface) can be any suitable surface. Suitable surfaces include, but are not limited to, silicon (Si), silicon dioxide (SiO₂), silicon oxide (SiOₓ), silicon oxycarbide (SiOC), platinum (Pt), titanium nitride (TiN), tantalum nitride (TaN), copper (Cu), cobalt (Cu), tungsten (W), ruthenium (Ru), molybdenum (Mo) or combinations thereof.

At operation 214, the processing chamber is purged to remove unreacted metal precursor, reaction products and by-products. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the metal precursor by any suitable technique including, but not limited to, moving the substrate through a gas curtain to a portion or sector of the processing chamber that contains none or substantially none of the metal precursor. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur.

At operation 216, the substrate (or substrate surface) is exposed to an oxidant to form a metal oxide film. The oxidant may be any suitable oxidant known to the skilled artisan, including, but not limited to one or more of water (H₂O), molecular oxygen (O₂), and ozone (O₃).

In one or more embodiments, the oxidant comprises an in situ steam generated (ISSG) oxidant. In some embodiments, a stream of ozone (O₃) and hydrogen (H₂) gas is co-flowed to generate steam in situ.

In one or more embodiments, ozone (O₃) gas is generated by an ozone generator. That gas is mixed with hydrogen (H₂) gas from the facilities near the reaction zone of the chamber. Because of safety concerns of mixing reactive gasses, the mixing point has to be at a low pressure. In one or more embodiments, a pressure switch is attached to the chamber and the pressure is maintained at 100 Torr or less during the mixing of the ozone (O₃) and hydrogen (H₂). In one or more embodiments, the ozone (O₃) and hydrogen (H₂) gases are mixed and flowed to a showerhead above a reaction zone where the gases then react with the metal species on the substrate to form a metal oxide film on the substrate.

In one or more embodiments, a gas source supplies oxygen gas (O₂) through a mass flow controller to an ozonator, which converts a large fraction of the oxygen to ozone gas (O₃). The resultant oxygen-based mixture of O₂ and O₃ and perhaps some oxygen radicals O* and ionized oxygen atoms or molecules is delivered into the processing chamber. In one or more embodiments, the stream of oxygen-containing gas is at least 30% ozone, or at least 70% ozone, or at least 80% ozone, or at least 90% ozone. Ozone is a metastable molecule which spontaneously quickly dissociates in the reaction.

In one or more embodiments, the ozone/oxygen containing gas mixture is combined with hydrogen (H₂) to increase the oxidation rate. In some embodiments, the hydrogen may be essentially pure hydrogen gas or be a forming gas of hydrogen (H₂)/nitrogen (N₂), for example having at least 7% hydrogen, or at least 10% hydrogen.

In one or more embodiments, an in situ steam generation (ISSG) process is used to mix the ozone/oxygen containing gas mixture and the hydrogen (H₂) gas. ISSG a low-pressure process (e.g. below 20 Torr) where the pre-mixed gases are introduced to the process chamber directly, without pre-combustion. Process gases are mixed and are then injected into the processing chamber, where they flow across a rotating substrate that is heated. The reaction between the ozone/oxygen and hydrogen occurs close to the substrate surface because the hot substrate acts as the ignition source. Steam is generated, which reacts with the metal species of the metal film on the surface of the substrate to form a metal oxide.

At operation 218, the processing chamber is purged after exposure to the oxidant. Purging the processing chamber in operation 218 can be the same process or different process than the purge in operation 214. Purging the processing chamber, portion of the processing chamber, area adjacent the substrate surface, etc., removes unreacted oxidant, reaction products and by-products from the area adjacent the substrate surface.

At operation 220, the substrate is exposed to a stream of forming gas hydrogen (H₂) and nitrogen (N₂) gas to anneal the metal-oxide film. In one or more embodiments, the anneal can be performed at a pressure in a range of from 10 Torr to 75 Torr, at a temperature in a range of from 300° C. to 500° C., and with an exposure time in a range of from 0.1 seconds to 10 seconds.

At operation 222, the processing chamber is purged. Purging the processing chamber in operation 222 can be the same process or different process than the purge in operation 218 and/or the purge in operation 214. Purging the processing chamber, portion of the processing chamber, area adjacent the substrate surface, etc., removes unreacted oxidant, reaction products and by-products from the area adjacent the substrate surface.

At decision point 224, the thickness of the deposited film, or number of cycles of metal-precursor, oxidant, and forming gas anneal is considered. If the deposited film has reached a predetermined thickness or a predetermined number of process cycles have been performed, the method 200 moves to an optional post-processing operation 226. If the thickness of the deposited film or the number of process cycles has not reached the predetermined threshold, the method 200 returns to operation 210 to expose the substrate surface to the metal precursor again in operation 212, and continuing.

The optional post-processing operation 226 can be, for example, a process to modify film properties (e.g., annealing) or a further film deposition process (e.g., additional ALD or CVD processes) to grow additional films. In some embodiments, the post-processing operation 226 can be a process that modifies a property of the deposited film. In some embodiments, the post-processing operation 226 comprises annealing the as-deposited metal oxide film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited film increases the density, decreases the resistivity and/or increases the purity of the film.

The method 200 can be performed at any suitable temperature depending on, for example, the metal precursor, oxidant or thermal budget of the device. In some embodiments, exposures to the metal precursor (operation 212) and the oxidant (operation 216) occur at the same temperature. In some embodiments, the substrate is maintained at a temperature in a range of about 300° C. to about 500° C., or in the range of about 350° C. to about 400° C.

In some embodiments, exposure to the metal precursor (operation 212) occurs at a different temperature than the exposure to the oxidant (operation 216). In some embodiments, the substrate is maintained at a first temperature in a range of about 300° C. to about 500° C. for the exposure to the metal precursor, and at a second temperature in the range of about 300° C. to about 500° C. for exposure the oxidant.

In some embodiments, the metal oxide film formed comprises a metal selected from one or more of aluminum (Al), zirconium (Zr), magnesium (Mg), hafnium (Hf), calcium (Ca), lanthanum (La), scandium (Sc), tantalum (Ta), titanium (Ti), niobium (Nb), yttrium (Y), gadolinium (Gd), zinc (Zn), indium (In), gallium (Ga), and tin (Sn).

In other embodiments, the metal oxide film comprises metal oxide (MOₓ) with an oxygen content of greater than or equal to about 10%, greater than or equal to about 15%, greater than or equal to about 20%, greater than or equal to about 25%, greater than or equal to about 30%, greater than or equal to about 35%, greater than or equal to about 40%, greater than or equal to about 45%, greater than or equal to about 50%, greater than or equal to about 55%, or greater than or equal to about 60% on an atomic basis. In some embodiments, the metal-containing film comprises an oxygen content in the range of about 2% to about 65%, or in the range of about 3% to about 65%, or in the range of about 4% to about 6%, on an atomic basis.

The deposition operation 210 can be repeated to form a metal oxide film having a predetermined thickness. In some embodiments, the deposition operation 210 is repeated to provide a metal oxide film having a thickness in the range of about 0.3 nm to about 10 nm, or in the range of about 30 Å to about 3000 Å.

One or more embodiments of the disclosure are directed to methods of depositing metal oxide films in high aspect ratio features. A high aspect ratio feature is a trench, via or pillar having a height:width ratio greater than or equal to about 10, 20 or 50. In some embodiments, the metal oxide film is deposited conformally on the high aspect ratio feature. As used in this manner, a conformal film has a thickness near the top of the feature that is in the range of about 80-120% of the thickness at the bottom of the feature.

Some embodiments of the disclosure are directed to methods for bottom-up gap fill of a feature. A bottom-up gap fill process fills the feature from the bottom versus a conformal process which fills the feature from the bottom and sides. In some embodiments, the feature has a first material at the bottom (e.g., a nitride) and a second material (e.g., an oxide) at the sidewalls. The metal oxide film deposits selectively on the first material relative to the second material so that the metal film fills the feature in a bottom-up manner.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reducing agent). According to one or more embodiments, a purge gas is injected at the exit of the deposition chamber to prevent reactants (e.g., reducing agent) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### Examples

ALD experiments are performed in an ALD reactor at process temperatures ranging from 300° C. to 400° C. on silicon without removal of the native oxide. The metal precursor trimethylaluminum is delivered into the reaction chamber at 100° C. ALD experiments are conducted in the sequence TMA pulse (1 S)-Purge (20 s)-in situ steam generated mixture of ozone/hydrogen pulse (1 s)-Purge (20 s).

ALD experiments are performed in an ALD reactor at process temperatures ranging from 400° C. to 450° C. on silicon without removal of the native oxide. The metal precursor trimethylaluminum is delivered into the reaction chamber at 100° C. ALD experiments are conducted in the sequence TMA pulse (1 s)-Purge (20 s)-ozone pulse (1 s)-Purge (20 s)-9:1 Nitrogen/Hydrogen pulse (1 s).

ALD experiments are performed in an ALD reactor at process temperatures ranging from 400° C. to 450° C. on silicon without removal of the native oxide. The metal precursor hafnium tetrachloride is delivered into the reaction chamber at 175° C. ALD experiments are conducted in the sequence hafnium tetrachloride pulse (1 s)-Purge (20 s)-water pulse (1 s)-Purge (20 s)-9:1 Nitrogen/Hydrogen pulse (1 s).

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A method of depositing a film, the method comprising:
exposing a substrate to a metal precursor in a processing chamber to deposit a metal film on the substrate;
purging the processing chamber of the metal precursor,
exposing the substrate to an in situ steam generated oxidant to react with the metal film and form a metal oxide film on the substrate, the in situ steam generated oxidant comprising a mixture of hydrogen (H₂) and at least 70% ozone (O₃); and
purging the processing chamber of the in situ steam generated oxidant.

2. The method of claim 1, wherein the metal precursor comprises a metal selected from one or more of aluminum (Al), zirconium (Zr), magnesium (Mg), hafnium (Hf), calcium (Ca), lanthanum (La), scandium (Sc), tantalum (Ta), titanium (Ti), niobium (Nb), yttrium (Y), gadolinium (Gd), zinc (Zn), indium (In), gallium (Ga), and tin (Sn).

3. The method of claim 1, wherein the metal oxide film comprises one or more of aluminum oxide, zirconium oxide, magnesium oxide, hafnium oxide, calcium oxide, lanthanum oxide, scandium oxide, tantalum oxide, titanium oxide, niobium oxide, yttrium oxide, gadolinium oxide, zinc oxide, indium oxide, gallium oxide, and tin oxide.

4. The method of claim 1, wherein the in situ steam generated oxidant is formed by generating ozone (O₃) gas and mixing the ozone (O₃) gas with hydrogen (H₂) gas.

5. The method of claim 1, wherein the substrate is exposed to the in situ steam generated oxidant at a pressure less than 100 Torr.

6. The method of claim 1, wherein the substrate has at least one feature thereon, the at least one feature extending a feature depth from a top surface of the substrate to a bottom surface, the at least one feature having a width defined by a first sidewall and a second sidewall.

7. The method of claim 1, wherein purging the processing chamber comprises flowing a purge gas into the processing chamber.

8. The method of claim 7, wherein the purge gas is selected from one or more of nitrogen (N₂), helium (He), and argon (Ar).

9. The method of claim 1, wherein the substrate is maintained at a temperature in a range of from about 300° C. to about 500° C.

10. The method of claim 1, further comprising repeating the method to provide the metal oxide film having a thickness of about 2 Å to 3000 Å.

11. A method of depositing a film, the method comprising:
exposing a substrate to a metal precursor in a processing chamber to deposit a metal film on the substrate;
purging the processing chamber of the metal precursor,
exposing the substrate to an oxidant to form a metal oxide film, the oxidant comprising one or more of (H₂O), molecular oxygen (O₂), and ozone (O₃);
purging the processing chamber of the oxidant;
annealing the metal oxide film in a stream consisting of hydrogen (H₂) gas and nitrogen (N₂) gas at a pressure in a range of from 10 Torr to 75 Torr and for a time period in a range of from 0.1 seconds to 10 seconds; and
purging the processing chamber of the hydrogen (H₂) gas and the nitrogen (N₂) gas.

12. The method of claim 11, wherein the metal precursor comprises a metal selected from one or more of aluminum (Al), zirconium (Zr), magnesium (Mg), hafnium (Hf), calcium (Ca), lanthanum (La), scandium (Sc), tantalum (Ta), titanium (Ti), niobium (Nb), yttrium (Y), gadolinium (Gd), zinc (Zn), indium (In), gallium (Ga), tin (Sn).

13. The method of claim 11, wherein the metal oxide film comprises one or more of aluminum oxide, zirconium oxide, magnesium oxide, hafnium oxide, calcium oxide, lanthanum oxide, scandium oxide, tantalum oxide, titanium oxide, niobium oxide, yttrium oxide, gadolinium oxide, zinc oxide, indium oxide, gallium oxide, and tin oxide.

14. The method of claim 11, wherein the substrate has at least one feature thereon, the at least one feature extending a feature depth from a top surface of the substrate to a bottom surface, the at least one feature having a width defined by a first sidewall and a second sidewall.

15. The method of claim 11, wherein purging the processing chamber comprises flowing a purge gas into the processing chamber.

16. The method of claim 15, wherein the purge gas is selected from one or more of nitrogen (N₂), helium (He), and argon (Ar).

17. The method of claim 11, wherein the substrate is maintained at a temperature in a range of from about 300° C. to about 500° C.

18. The method of claim 11, further comprising repeating the method to provide the metal oxide film having a thickness of about 2 Å to about 3000 Å.

19. The method of claim 11, wherein the oxidant comprises an in situ steam generated oxidant formed by generating ozone (O₃) gas and mixing the ozone (O₃) gas with hydrogen (H₂) gas.

20. A method of depositing a film, the method comprising:
selectively forming a metal oxide film in a process cycle comprising sequential exposure of a substrate to a metal precursor, purge gas, oxidant, purge gas, an atmosphere consisting of hydrogen (H₂) and nitrogen (N₂), and purge gas, wherein the atmosphere consisting of hydrogen (H₂) and nitrogen (N₂) anneals the metal oxide film and wherein the substrate is exposed to the atmosphere consisting of hydrogen (H₂) and nitrogen (N₂) at a pressure in a range of from 10 Torr to 75 Torr and for a time period in a range of from 0.1 seconds to 10 seconds.
